(19) United States
(12) Patent Application Publication
(10) Pub. No.: US 2026/0231655 A1
(43) Pub. Date: Aug. 6, 2026

(54) DISPLAY APPARATUS HAVING A DISPLAY PANEL AND LENTICULAR LENSES

(71) Applicant: LG Display Co., Ltd., Seoul (KR)

(72) Inventors: Ju Seong PARK, Paju-si (KR); Joung Won WOO, Paju-si (KR); Wook JEON, Paju-si (KR)

(73) Assignee: LG Display Co., Ltd., Seoul (KR)

(21) Appl. No.: 19/440,348

(22) Filed: Jan. 5, 2026

(30) Foreign Application Priority Data
Jan. 31, 2025 (KR) 10-2025-0012385

(51) Int. Cl. H10K 59/80; H10K 59/131; H10K 59/35

(52) U.S. Cl. CPC H10K 59/879; H10K 59/131; H10K 59/352; H10K 59/8792

(57) ABSTRACT

A display apparatus including a display panel and lenticular lenses is provided. The lenticular lenses can be disposed side by side on the display panel in a first direction. Each of the lenticular lenses can extend in a second direction perpendicular to the first direction. The display panel can include pixel rows disposed side by side in the second direction. Each of the pixel rows can include pixel areas repeated in a specific order in the first direction. The pixel areas of each pixel row can include first pixel areas having a same size and a second pixel area having a longer length than each first pixel area in the first direction. Thus, in the display apparatus, the occurrence of spots in realized image can be prevented or minimized.

### CROSS-REFERENCE TO RELATED APPLICATIONS

This application claims priority to Korean Patent Application No. 10-2025-0012385, filed in the Republic of Korea on January 31, 2025, which is hereby expressly incorporated by reference as if fully set forth herein.

### BACKGROUND

### Field

The present disclosure relates to a display apparatus in which lenticular lenses are disposed on a display panel.

### Discussion of the Related Art

Generally, a display apparatus provides an image to a user. For example, the display apparatus can include light-emitting devices. Each of the light-emitting devices can emit light displaying a specific color. For example, each of the light-emitting devices can include a light-emitting unit between a first electrode and a second electrode. The light-emitting devices can be disposed on the pixel areas of a device substrate. An encapsulation structure can be disposed on the light-emitting devices. The image generated by the light-emitting devices can be three-dimensionally recognized by the user. For example, lenticular lenses can be disposed side by side on the encapsulation structure.

### SUMMARY OF THE DISCLOSURE

Accordingly, the present disclosure is directed to a display apparatus that substantially obviates one or more problems due to limitations and disadvantages of the related art.

An object of the present disclosure is to provide a display apparatus capable of preventing or minimizing the occurrence of spots in an image provided to a user.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a display panel. The display panel includes pixel rows. Each of the pixel rows includes pixel areas displaying different colors. The pixel areas of each pixel row are repeated in a specific order in a first direction. The pixel rows are disposed side by side in a second direction perpendicular to the first direction. Each of the pixel rows includes first pixel areas and a second pixel area. The first pixel areas have a same size. The second pixel area has a longer length than each first pixel area in the first direction. The second pixel area of each pixel row is disposed between an edge of the display panel and the first pixel areas of the corresponding pixel row. Lenticular lenses are disposed on the display panel. The lenticular lenses are disposed side by side in the first direction. Each of the lenticular lenses extends in the second direction.

According to aspects of the present disclosure, a distance between the edge of the display panel and each pixel row can be the same.

According to aspects of the present disclosure, the pixel rows can include a first pixel row and a second pixel row. The second pixel row can be disposed adjacent to the first pixel row in the second direction. Each first pixel area of the second pixel row can have a same size as each first pixel area of the first pixel row. The second pixel area of the second pixel row can have a different length from the second pixel area of the first pixel row in the first direction.

According to aspects of the present disclosure, the second pixel area of the second pixel row can have a same length as the second pixel area of the first pixel row in the second direction.

According to aspects of the present disclosure, the pixel rows can include a third pixel row disposed adjacent to the second pixel row in the second direction. Each first pixel area of the third pixel row can have a same size as each first pixel area of the second pixel row. The second pixel area of the third pixel row can have a same size as the second pixel area of the first pixel row in the first direction.

According to aspects of the present disclosure, the second pixel area of the second pixel row can display a different color from the second pixel area of the first pixel row. The second pixel area of the third pixel row can display a different color from the second pixel area of the first pixel row and the second pixel area of the second pixel row.

According to aspects of the present disclosure, a difference in the length of the second pixel area of the second pixel row and the second pixel area of the third pixel row in the first direction can be a same as a difference in the length of the second pixel area of the first pixel row and the second pixel area of the second pixel row in the first direction.

According to aspects of the present disclosure, a difference in the length of the second pixel area of the first pixel row and the second pixel area of the second pixel row in the first direction can be smaller than a length of each first pixel area of the first pixel row in the first direction.

According to aspects of the present disclosure, the display panel can include a first side and a second side. The first side and the second side of the display panel can extend in the second direction. The second side of the display panel can be opposite to the first side of the display panel. The second pixel area of the first pixel row can be disposed adjacent to the first side of the display panel. The second pixel area of the third pixel row can be disposed adjacent to the second side of the display panel.

According to aspects of the present disclosure, the second pixel row can be disposed between the first pixel row and the third pixel row. The second pixel area of the second pixel row can disposed between the first side of the display panel and the first pixel areas of the second pixel row and between the first pixel areas of the second pixel row and the second side of the display panel.

According to aspects of the present disclosure, color filters can be disposed in the pixel areas of each pixel row. The second pixel area of each pixel row can include a first color filter and a second color filter. The second color filter can be disposed side by side with the first color filter in the first direction. The second color filter can include a different material from the first color filter.

According to aspects of the present disclosure, the first color filter can be disposed between an edge of the display panel and the second color filter. A length of the second color filer in the first direction can be a same as a length of each first pixel area in the first direction. A length of the first color filter in the first direction can be smaller than the length of the second color filter in the first direction.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain the principle of the present disclosure. In the drawings:

FIG. 1 is a view schematically showing a display apparatus according to one or more embodiments of the present disclosure;

FIG. 2 is an example of an enlarged view of K1 region in FIG. 1;

FIG. 3 is an example of an enlarged view of K2 region in FIG. 1;

FIG. 4 is a view showing an example of a circuit of a pixel area in the display apparatus according to one or more embodiments of the present disclosure;

FIG. 5 is an example of a view taken along line I-I’ of FIG. 2;

FIG. 6 is an example of a view taken along line II-II’ of FIG. 2;

FIG. 7 is an example of a view taken along line III-III’ of FIG. 2; and

FIGS. 8 to 13 are views showing a display apparatus according to another embodiment of the present disclosure.

### DETAILED DESCRIPTION OF THE EMBODIMENTS

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being "on" a second element, although the first element can be disposed on the second element so as to come into contact with the second element, a third element can be interposed between the first element and the second element.

Here, terms such as, for example, “first,” “second,” etc. can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms such as "comprises" and "includes" specify the presence of stated features, integers, steps, operations, elements, components, and/or combinations thereof, but do not preclude the presence or addition of one or more other features, integers, steps, operations, elements, components, and/or combinations thereof.

Further, unless 'directly' is used, the terms such as "connected" and "coupled" can include that two components are "connected" or "coupled" through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

In addition, the term “can” fully encompasses all the meanings and coverages of the term “may” and vice versa.

### Embodiments

Now, various embodiments of the present disclosure will be discussed referring to the drawings. All the components of each display apparatus/device according to all embodiments of the present disclosure are operatively coupled and configured.

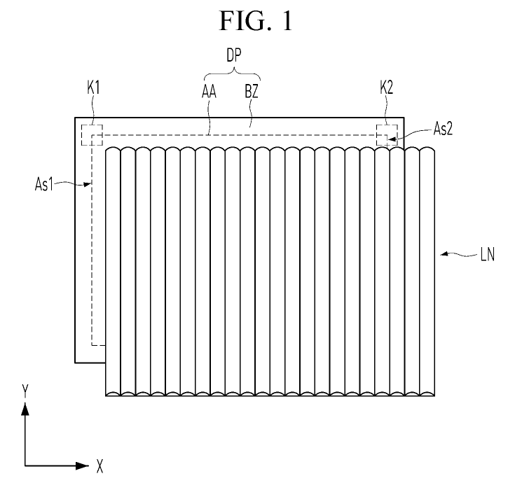

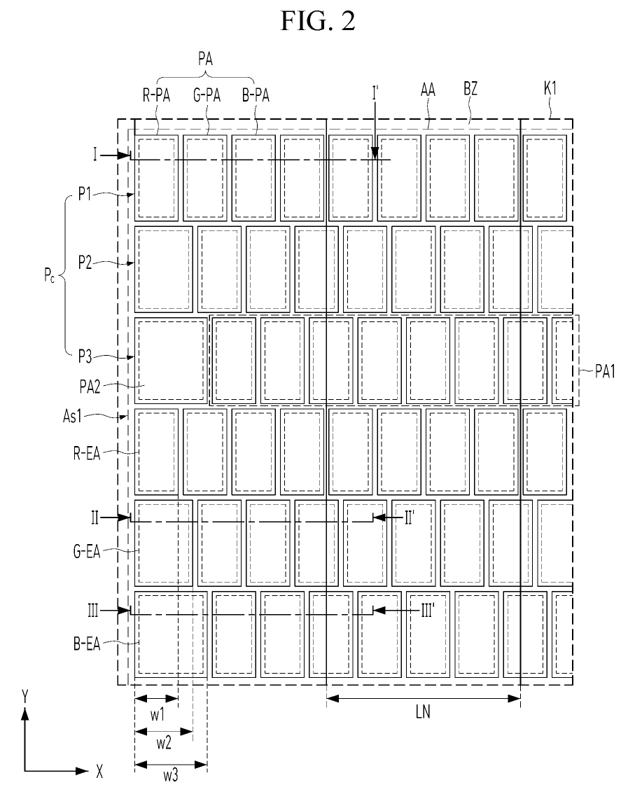

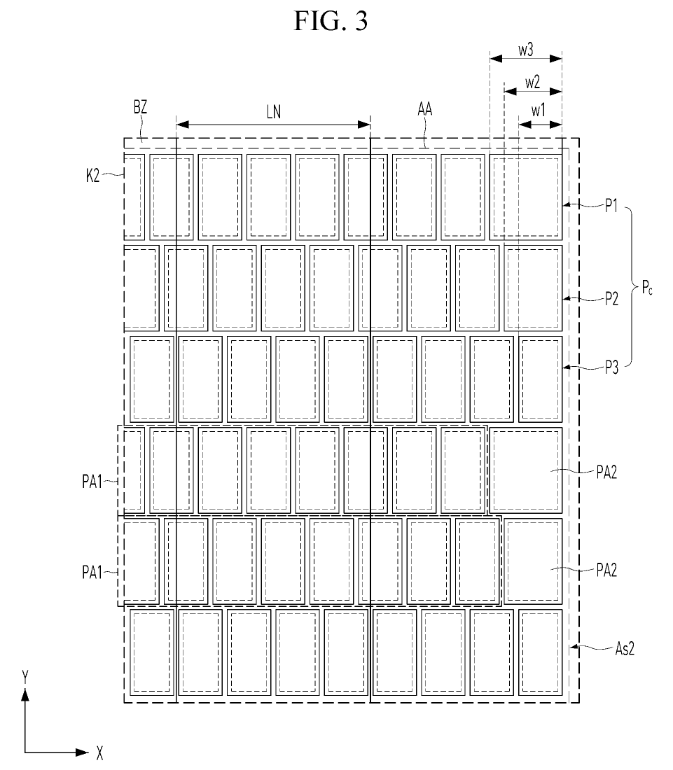

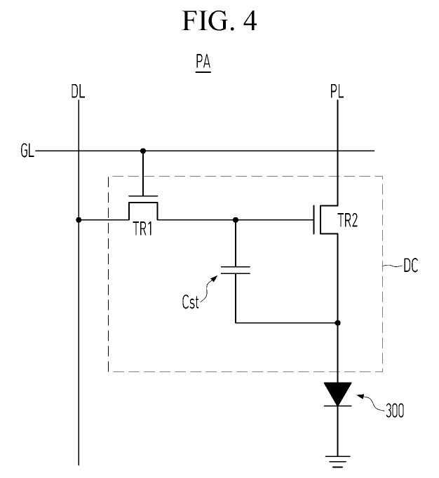

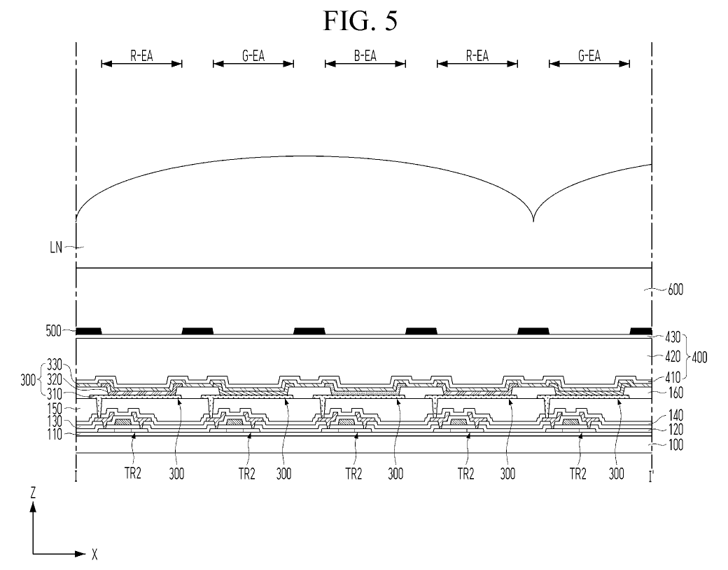

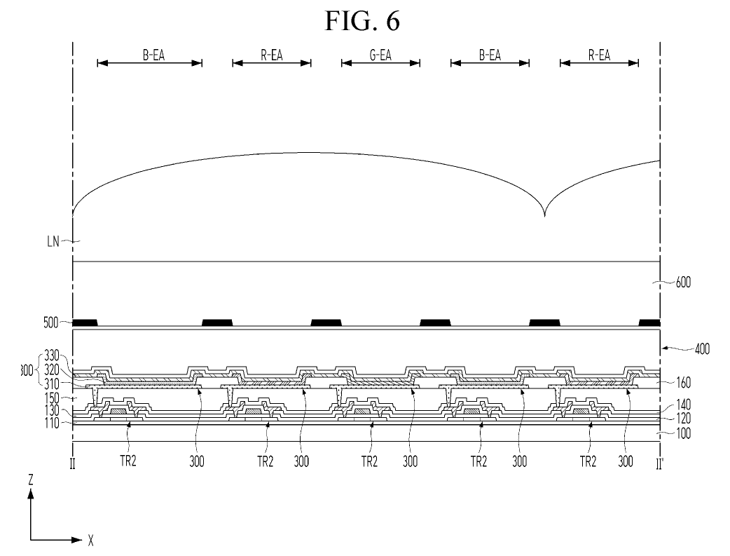

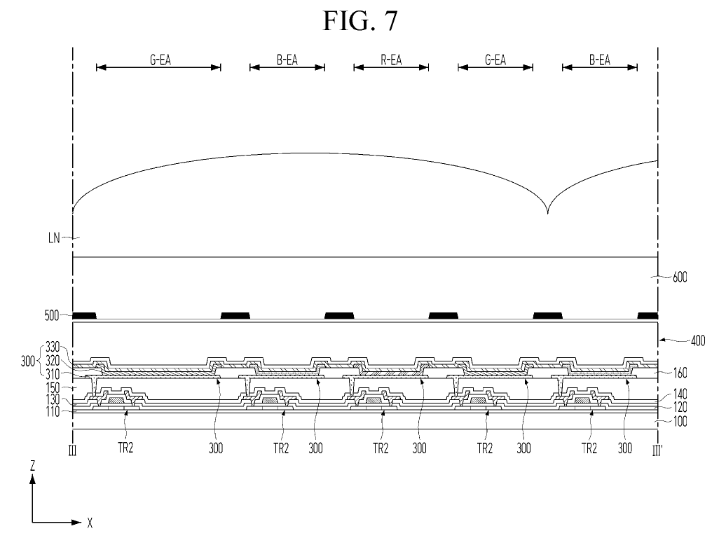

FIG. 1 is a view schematically showing a display apparatus according to one or more embodiments of the present disclosure. FIG. 2 is an enlarged view of K1 region in FIG. 1. FIG. 3 is an enlarged view of K2 region in FIG. 1. FIG. 4 is a view showing a circuit of a pixel area in the display apparatus according to one or more embodiments of the present disclosure. FIG. 5 is a view taken along line I-I’ of FIG. 2. FIG. 6 is a view taken along line II-II’ of FIG. 2. FIG. 7 is a view taken along line III-III’ of FIG. 2.

Referring to FIGS. 1 to 7, the display apparatus according to one or more embodiments of the present disclosure can include a display panel DP. The display panel DP can generate an image provided to a user. For example, the display panel DP can include pixel areas PA. Each of the pixel areas PA can display a specific color. For example, each of the pixel areas PA can be one of a red pixel area R-PA displaying a red color, a green pixel area G-PA displaying a green color and a blue pixel area B-PA displaying a blue color.

Various signals can be applied in each pixel area PA through signal wirings GL, DL and PL. The signal wirings GL, DL and PL can include a gate line GL applying a gate signal, a data line DL applying a data signal, and a power voltage supply line PL supplying a power voltage. A driving circuit DC electrically connected to the signal wirings GL, DL and PL and a light-emitting device 300 electrically connected to the driving circuit DC can be disposed within each pixel area PA. For example, the driving circuit DC of each pixel area PA can provide a driving current corresponding to the data signal to the light-emitting device 300 of the corresponding pixel area PA by using the power voltage according to the gate signal for one frame. The driving circuit DC of each pixel area PA can include a first thin film transistor TR1, a second thin film transistor TR2 and a storage capacitor Cst.

The first thin film transistor TR1 can transmit the data signal to the second thin film transistor TR2 according to the gate signal. For example, the first thin film transistor TR1 can function as a switching thin film transistor. The second thin film transistor TR2 can generate the driving current corresponding to the data signal by using the power voltage. For example, the second thin film transistor TR2 can function as a driving thin film transistor. The operation of the second thin film transistor TR2 can be maintained by the storage capacitor Cst for one frame. For example, the storage capacitor Cst can be electrically connected to a gate electrode and a source electrode of the second thin film transistor TR2.

The driving circuit DC of each pixel area PA can be disposed on a device substrate 100. The device substrate 100 can include an insulating material. For example, the device substrate 100 can include glass or plastic. At least one insulating layers 110, 120, 130, 140, 150 and 160 for preventing unintended electrical connection can be disposed on the device substrate 100. For example, a buffer insulating layer 110, a gate insulating layer 120, an interlayer insulating layer 130, a device passivation layer 140, a device planarization layer 150 and a bank insulating layer 160 can be disposed on the device substrate 100.

The buffer insulating layer 110 can be disposed on the device substrate 100. The gate insulating layer 120 can be disposed on the buffer insulating layer 110. The interlayer insulating layer 130 can be disposed on the gate insulating layer 120. The device passivation layer 140 can be disposed on the interlayer insulating layer 130. The buffer insulating layer 110, the gate insulating layer 120, the interlayer insulating layer 130 and the device passivation layer 140 can include an insulating material. The driving circuit DC of each pixel area PA can be disposed between the buffer insulating layer 110 and the device passivation layer 140. For example, the damage of the driving circuit DC in each pixel area PA due to external impact and moisture can be prevented or minimized by the device passivation layer 140.

The device planarization layer 150 can be disposed on the device passivation layer 140. The device planarization layer 150 can include an insulating material. The device planarization layer 150 can include a material having a higher fluidity than the buffer insulating layer 110, the gate insulating layer 120, the interlayer insulating layer 130 and the device passivation layer 140. For example, the buffer insulating layer 110, the gate insulating layer 120, the interlayer insulating layer 130 and the device passivation layer 140 can include an inorganic insulating material, and the device planarization layer 150 can include an organic insulating material. A thickness difference due to the driving circuit DC of each pixel area PA can be removed by the device planarization layer 150.

The light-emitting device 300 of each pixel area PA can be disposed on the device planarization layer 150. The light-emitting device 300 of each pixel area PA can emit light displaying a specific color. For example, the light-emitting device 300 of each pixel area PA can include a first electrode 310, a light-emitting unit 320 and a second electrode 330, which are sequentially stacked.

The first electrode 310 and the second electrode 330 can include a conductive material. The second electrode 330 can include a different material from the first electrode 310. For example, a transmittance of the second electrode 330 can be higher than a transmittance of the first electrode 310. The first electrode 310 can have a higher reflectance than the second electrode 330. For example, the first electrode 310 can be a reflective electrode including a metal, such as aluminum (Al) and silver (Ag), and the second electrode 330 can be a transparent electrode made of a transparent conductive material, such as ITO and IZO.

The light-emitting unit 320 can generate light having luminance corresponding to a voltage difference between the first electrode 310 and the second electrode 330. For example, the light-emitting unit 320 can include an emission material layer (EML). The light generated by the light-emitting unit 320 can be emitted through the second electrode 330. The light-emitting unit 320 can have a multi-layer structure. For example, the light-emitting unit 320 can further include at least one of a hole injection layer (HIL), a hole transport layer (HTL), an electron transport layer (ETL) and an electron injection layer (EIL).

The bank insulating layer 160 can be disposed on the device planarization layer 150. The bank insulating layer 160 can include an insulating material. For example, the bank insulating layer 160 can include an organic insulating material. The first electrode 310 of each pixel area PA can be insulated from the first electrode 310 of adjacent pixel area PA by the bank insulating layer 160. For example, an edge of the first electrode 310 in each pixel area PA can be covered by the bank insulating layer 160. The bank insulating layer 160 can partially expose the first electrode 310 of each pixel area PA. For example, an emission area R-EA, G-EA and B-EA can be defined in each pixel area PA by the bank insulating layer 160.

The light-emitting unit 320 of each pixel area PA can be in direct contact with a portion of the first electrode 310 exposed by the bank insulating layer and the second electrode 330 in the corresponding pixel area PA. For example, the emission area R-EA, G-EA and B-EA of each pixel area PA can be a region in which light is generated. A region disposed between the emission areas R-EA, G-EA and B-EA can be a non-emission area in which light is not generated. For example, in the display apparatus according to the embodiment of the present disclosure, a red emission area R-EA can be defined in the red pixel area R-PA by the bank insulating layer 160, a green emission area G-EA can be defined in the green pixel area G-PA by the bank insulating layer 160, and a blue emission area B-EA can be defined in the blue pixel area B-PA by the bank insulating layer 160.

The light generated by the light-emitting unit 320 of each pixel area PA can display a different color from the light generated by the light-emitting unit 320 of adjacent pixel area PA. For example, in the display apparatus according to the embodiment of the present disclosure, the light-emitting unit 320 of the red pixel area R-PA can include a red emission material layer, the light-emitting unit 320 of the green pixel area G-PA can include a green emission material layer, and the light-emitting unit 320 of the blue pixel area B-PA can include a blue emission material layer. The light-emitting unit 320 of each pixel area PA can be spaced apart from the light-emitting unit 320 of adjacent pixel area PA on the bank insulating layer 160.

A signal applied to the second electrode 330 of each pixel area PA can be a same as a signal applied to the second electrode 330 of adjacent pixel area PA. For example, the second electrode 330 of each pixel area PA can be electrically connected to the second electrode 330 of adjacent pixel area PA. The second electrode 330 of each pixel area PA can be formed simultaneously with the second electrode 330 of adjacent pixel area PA. For example, the second electrode 330 of each pixel area PA can be in direct contact with the second electrode 330 of adjacent pixel area PA. Thus, in the display apparatus according to the embodiment of the present disclosure, a process of forming the second electrode 330 in each pixel area PA can be simplified.

An encapsulation structure 400 can be disposed on the light-emitting device 300 of each pixel area PA. The encapsulation structure 400 can prevent the damage of the light-emitting devices 300 in each pixel area PA due to the external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a material having a higher fluidity than the first encapsulating layer 410 and the third encapsulating layer 430. For example, the first encapsulating layer 410 and the third encapsulating layer 430 can include an inorganic encapsulating layer made of an inorganic insulating material, and the second encapsulating layer 420 can include an organic encapsulating layer made of an organic insulating material. A thickness difference due to the light-emitting device 300 of each pixel area PA can be removed by the second encapsulating layer 420.

A barrier pattern 500 can be disposed on the encapsulation structure 400. The barrier pattern 500 can include a material capable of blocking light. For example, the barrier pattern 500 can include a black dye, such as carbon black. The barrier pattern 500 can overlap with the non-emission area. For example, each of the emission areas R-EA, G-EA and B-EA can’t overlap with the barrier pattern 500. Thus, in the display apparatus according to the embodiment of the present disclosure, a travelling direction of the light emitted from the light-emitting device 300 of each pixel area PA can be restricted by the barrier pattern 500. For example, in the display apparatus according to the embodiment of the present disclosure, the unintended color mixing can be prevented or minimized by the barrier pattern 500. Therefore, in the display apparatus according to the embodiment of the present disclosure, the quality of the image realized by the light emitted from the light-emitting device 300 of each pixel area PA can be improved.

An optical insulating layer 600 can be disposed on the barrier pattern 500. The optical insulating layer 600 can include an insulating material. The optical insulating layer 600 can include a transparent material. For example, the optical insulating layer 600 can include an organic insulating material. The optical insulating layer 600 can include a region overlapping with the emission area R-EA, G-EA and B-EA of each pixel area PA. For example, the barrier pattern 500 can be covered by the optical insulating layer 600. Thus, in the display apparatus according to the embodiment of the present disclosure, the light generated by the light-emitting device 300 of each pixel area PA can be emitted through the optical insulating layer 600. Therefore, in the display apparatus according to the embodiment of the present disclosure, the optical distance of the light emitted from the light-emitting device 300 in each pixel area PA can be sufficiently secured.

The display panel DP can include a display area AA and a bezel area BZ. The pixel areas PA can be disposed within the display area AA. The bezel area BZ ca be disposed outside the display area AA. For example, the display area AA can be surrounded by the bezel area BZ. A gate driver electrically connected to the gate line GL, a data driver electrically connected to the data line DL, and a power unit electrically connected to the power voltage supply line PL can be disposed outside the display area AA. For example, at least one of the gate driver, the data driver and the power unit can be disposed on the bezel area BZ.

In the display apparatus according to the embodiment of the present disclosure, the image realized by the pixel areas PA of the display panel DP can be three-dimensionally recognized by the user. For example, lenticular lenses LN can be disposed on the display panel DP. A surface of each lenticular lens LN opposite to the display panel DP can have a convex shape. Each of the lenticular lenses LN can be fixed on the display panel DP. For example, a lower surface of each lenticular lens LN toward the device substrate 100 can be in direct contact with the optical insulating layer 600.

The lenticular lenses LN can be disposed side by side in a first direction X. Each of the lenticular lenses LN can extend in a second direction Y perpendicular to the first direction X. The image three-dimensionally recognized by the user can be realized by a light field manner. For example, in the display apparatus according to the embodiment of the present disclosure, the display panel DP can include pixel rows Pc disposed side by side in the second direction Y, each of the pixel rows Pc can include the pixel areas PA disposed side by side in the first direction X, the pixel areas PA of each pixel row Pc can be arranged alternately with the pixel areas PA of the pixel row Pc adjacent in the second direction Y, as shown in FIGS. 2 and 3. A boundary between the pixel areas PA of each pixel row Pc can be spaced apart from the boundary between the pixel areas PA of the pixel row adjacent in the second direction Y in the first direction X. For example, the display apparatus according to the embodiment of the present disclosure can be a light-field display (LFD) apparatus in which the pixel areas PA of the display panel DP are disposed in a direction inclined to an extending direction of the lenticular lenses LN.

The pixel areas PA of each pixel row Pc can be repeated in a specific order. The pixel areas PA of each pixel row Pc can be arranged in a same order as the pixel areas PA of adjacent pixel row Pc. For example, in the display apparatus according to the embodiment of the present disclosure, the pixel areas PA of each pixel row Pc can be repeatedly arranged in the order of the red pixel area R-PA, the green pixel area G-PA and the blue pixel area B-PA in the first direction X.

The pixel areas PA of each pixel row Pc can have a same length in the second direction Y. At least one of the pixel areas PA in each pixel row Pc can have a longer length than another pixel areas PA of the corresponding pixel row Pc in the first direction X. For example, each of the pixel row Pc can include first pixel areas PA1 having a same size and a second pixel area PA2 having a longer length than each first pixel area PA1 in the first direction X.

Each of the first pixel areas PA1 can have a first horizontal length w1 in the first direction X. The first horizontal length w1 of each first pixel area PA1 can be smaller than a vertical length of each first pixel area PA1. A difference in the location of the pixel areas PA in the first direction X at two pixel rows Pc adjacent in the second direction Y can be smaller than the first horizontal length w1. For example, in the display apparatus according to the embodiment of the present disclosure, the pixel rows Pc can include a first pixel row P1, a second pixel row P2 in which a boundary between the pixel areas PA is shifted by 1/3 of the first horizontal length w1 in the first direction X from the boundary between the pixel areas PA of the first pixel row P1, and a third pixel row P3 in which a boundary between the pixel areas PA is shifted by 2/3 of the first horizontal length w1 in the first direction X from the boundary between the pixel areas PA of the first pixel row P1. The pixel rows Pc of the display area AA can be repeatedly arranged in order of the first pixel row P1, the second pixel row P2 and the third pixel row P3 in the second direction Y.

The second pixel area PA2 of the second pixel row P2 can have a different length from the second pixel area PA2 of the first pixel row P1 in the first direction X. The second pixel area PA2 of the third pixel row P3 can have a different length from the second pixel area PA2 of the second pixel row P2 in the first direction X. The second pixel area PA2 of the first pixel row P1 can have a same length as the second pixel area PA2 of the third pixel row P3 in the first direction X. For example, in the display apparatus according to the embodiment of the present disclosure, the second pixel area PA2 of the second pixel row P2 can have a second horizontal length w2 in the first direction X, the second pixel area PA2 of the first pixel row P1 and the second pixel area PA2 of the third pixel row P3 can have a third horizontal length w3 in the first direction X, and the second horizontal length w2 can be longer than the first horizontal length w1 by 1/3 of the first horizontal length w1, and the third horizontal length w3 can be longer than the second horizontal length w2 by 1/3 of the first horizontal length w1. For example, in the display apparatus according to the embodiment of the present disclosure, a difference between the second horizontal length w2 and the third horizontal length w3 can be a same as a difference between the first horizontal length w1 and the second horizontal length w2.

The second pixel area PA2 of each pixel row Pc can be disposed adjacent to an edge of the display area AA. For example, in the display apparatus according to the embodiment of the present disclosure, the display area AA can include a first side As1 extending in the second direction Y and a second side AS2 opposite to the first side As1, the second pixel area PA2 of the first pixel row P1 can be disposed between the first pixel areas PA1 of the first pixel row P1 and the second side As2 of the display area AA, the second pixel area PA2 of the second pixel row P2 can be disposed between the first side As1 of the display area AA and the first pixel areas PA1 of the second pixel row P2 and between the first pixel areas PA1 of the second pixel row P2 and the second side As2 of the display area AA, and the second pixel area PA2 of the third pixel row P3 can be disposed between the first side As1 of the display area AA and the first pixel areas PA1 of the third pixel row P3, as shown in FIGS. 1 to 3. Thus, in the display apparatus according to the embodiment of the present disclosure, an empty space occurred by a difference in the location of the pixel rows Pc adjacent in the second direction Y can be removed by the second pixel area PA2 of each pixel row Pc. For example, in the display apparatus according to the embodiment of the present disclosure, a distance between an edge of the display panel DP and each pixel row Pc can be the same.

The empty space occurred by a difference in the location of the pixel rows Pc adjacent in the second direction Y can be enlarged by one of the lenticular lenses LN. For example, the empty space by a difference in the location of the pixel rows Pc adjacent in the second direction Y can be seen as spots in the image recognized by the user. Thus, in the display apparatus according to the embodiment of the present disclosure, the occurrence of spots in the image recognized by the user can be prevented or minimized.

Accordingly, the display apparatus according to the embodiment of the present disclosure can comprise the display panel DP and the lenticular lenses LN disposed side by side on the display panel DP in the first direction X, wherein each lenticular lens LN can extend in the second direction Y, wherein the display panel DP can include the pixel rows Pc in which the pixel area PA displaying different colors are repeated in a specific order in the first direction X, wherein each of the pixel rows Pc disposed side by side in the second direction Y can include the first pixel areas PA1 having a same size and the second pixel area PA2 having a longer length than each first pixel area PA1 in the first direction X, and wherein the second pixel area PA2 of each pixel row Pc can be disposed between an edge of the display panel DP and the first pixel areas PA1 of the corresponding pixel row Pc. Thus, in the display apparatus according to the embodiment of the present disclosure, the empty space occurred by a difference in the location of the pixel rows Pc adjacent in the second direction Y can be filled by the second pixel area PA2 of one of the pixel rows Pc. Therefore, in the display apparatus according to the embodiment of the present disclosure, the occurrence of spots can be prevented or minimized in the image recognized by the user.

Further, in the display apparatus according to the embodiment of the present disclosure, the empty space occurred by a difference in the location of the pixel rows Pc adjacent in the second direction Y can be removed by increasing a horizontal length of one of the pixel areas PA of the corresponding pixel row Pc. For example, in the display apparatus according to the embodiment of the present disclosure, the empty space occurred by a difference in the location of the pixel rows Pc adjacent in the second direction Y can be removed, without additional process. Thus, in the display apparatus according to the embodiment of the present disclosure, the production energy can be reduced by the process optimization.

The display apparatus according to the embodiment of the present disclosure is described that the driving circuit DC of each pixel area PA consists of or includes the first thin film transistor TR1, the second thin film transistor TR2 and the storage capacitor Cst. However, in the display apparatus according to another embodiment of the present disclosure, the driving circuit DC of each pixel area PA can include a plurality of switching thin film transistors. For example, in the display apparatus according to another embodiment of the present disclosure, the driving circuit DC of each pixel area PA can further include a third thin film transistor to initialize the storage capacitor Cst according to the gate signal. The signal wirings GL, DL and PL can include an initial line applying a signal for initializing the storage capacitor Cst. Thus, in the display apparatus according to another embodiment of the present disclosure, the degree of freedom in the configuration of the driving circuit DC in each pixel area PA can be improved.

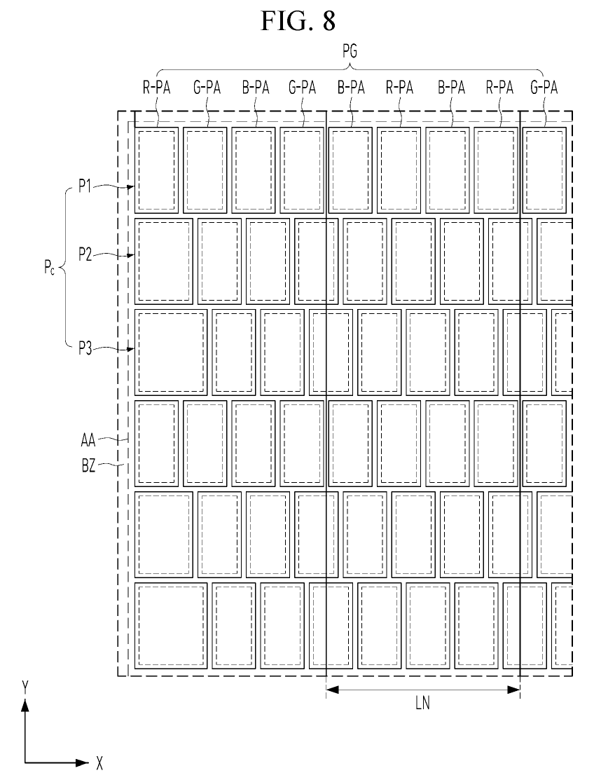

The display apparatus according to the embodiment of the present disclosure is described that the pixel areas PA of each pixel row Pc is repeatedly arranged in order of the red pixel area R-PA, the green pixel area G-PA and the blue pixel area B-PA in the first direction X. However, in the display apparatus according to another embodiment of the present disclosure, the pixel areas PA of each pixel row Pc can have various arrangements. For example, in the display apparatus according to another embodiment of the present disclosure, the pixel areas PA of each pixel row Pc can include pixel groups PG repeated in the first direction X, each of the pixel groups PG can include the red pixel area R-PA, the green pixel area G-PA, the blue pixel area B-PA, the green pixel area G-PA, the blue pixel area B-PA, the red pixel area R-PA, the blue pixel area B-PA, the red pixel area R-PA and the green pixel area G-PA, which are disposed side by side in the first direction X, as shown in FIG. 8. Thus, in the display apparatus according to another embodiment of the present disclosure, the image three-dimensionally recognized by the user can be effectively realized by the pixel rows Pc of the display panel.

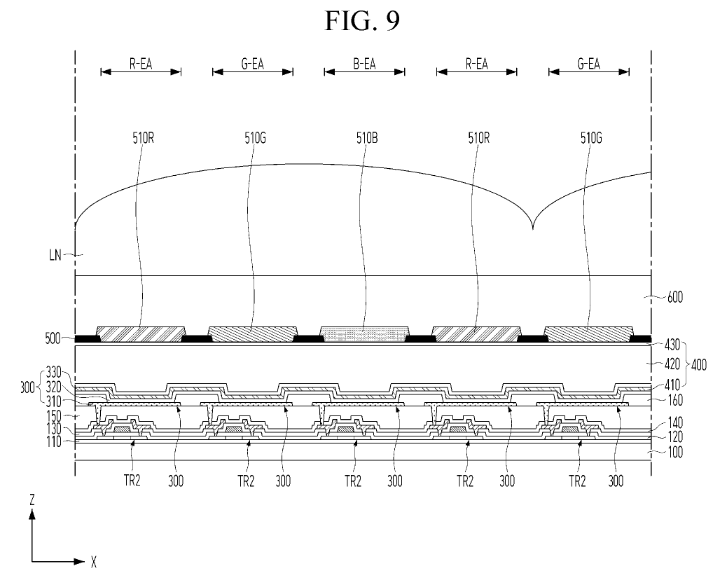

The display apparatus according to the embodiment of the present disclosure is described that the light generated by the light-emitting unit 320 of each pixel area PA displays a different color from the light generated by the light-emitting unit 320 of adjacent pixel area PA. However, in the display apparatus according to another embodiment of the present disclosure, the emission area R-EA, G-EA and B-EA of each pixel area PA can realize a specific color using color filters. For example, in the display apparatus according to another embodiment of the present disclosure, the light-emitting unit 320 of each pixel area PA can be in direct contact with the light-emitting unit 320 of adjacent pixel area PA on the bank insulating layer 160, as shown in FIG. 9. The light-emitting unit 320 of each pixel area PA can emit a white light.

Color filters 510R, 510G and 510B can be disposed on a path of the light emitted from the light-emitting unit 320 of each pixel area PA. For example, the color filters 510R, 510G and 510B can be disposed between the encapsulation structure 400 and the optical insulating layer 600. The color filters 510R, 510G and 510B can include a red color filter 510R overlapping with the red emission area R-EA, a green color filter 510G overlapping with the green emission area G-EA and a blue color filter 510B overlapping with the blue emission area B-EA. Thus, in the display apparatus according to another embodiment of the present disclosure, a process of forming the light-emitting unit 320 of each pixel area PA can be simplified. And, in the display apparatus according to another embodiment of the present disclosure, the degree of freedom in the configuration of the light-emitting unit 320 on each pixel area PA can be improved.

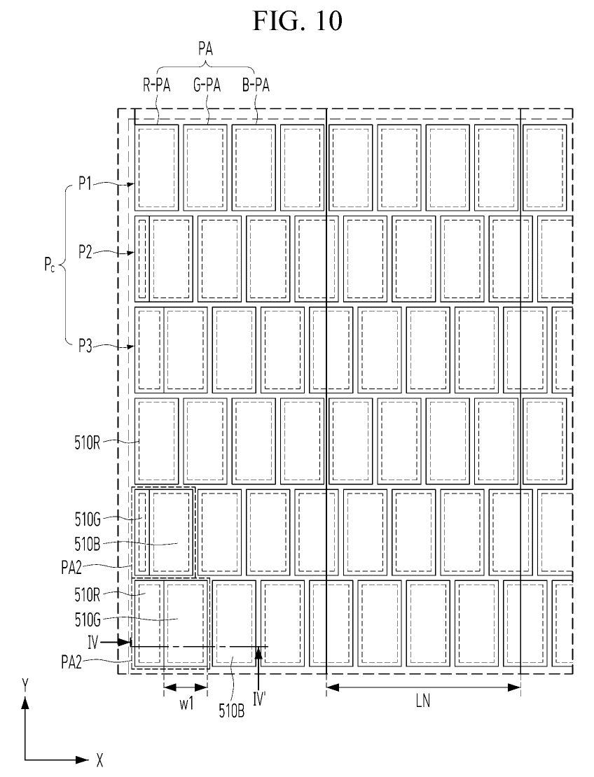

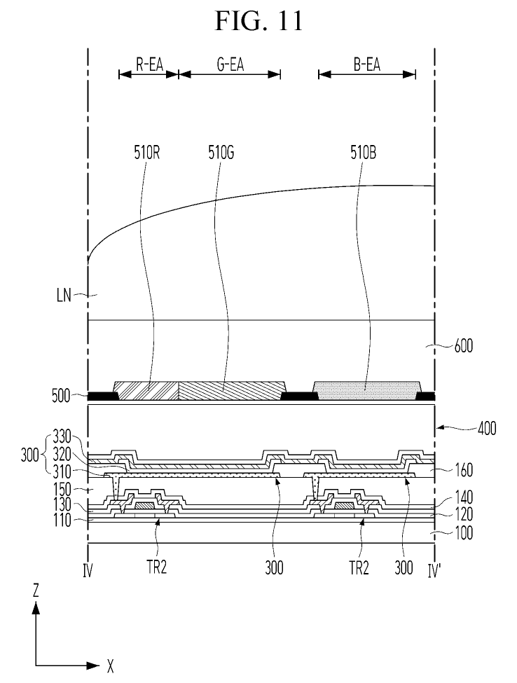

The display apparatus according to the embodiment of the present disclosure is described that the second pixel area PA2 of each pixel row Pc realizes a single color. However, in the display apparatus according to another embodiment of the present disclosure, the second pixel area PA2 of each pixel row Pc can display at least two colors. For example, in the display apparatus according to another embodiment of the present disclosure, the light-emitting unit 320 of each pixel area PA can emit a white light, and two color filters 510R, 510G and 510B can be disposed within the second pixel area PA2 of each pixel row Pc, as shown in FIGS. 10 and 11. FIG. 11 is an example of a view taken along line IV-IV’ of FIG. 10.

Colors displayed by two color filters 510R, 510G and 510B within the second pixel area PA2 of each pixel row Pc can be correspond to the repeatedly arrangement of the pixel areas PA constituting the corresponding pixel row Pc. For example, in the display apparatus according to another embodiment of the present disclosure, the red color filter 510R and the green color filter 510G can be disposed within the second pixel area PA2 of each third pixel row P3, the green color filter 510G can have the first horizontal length w1 in the first direction X, and the red color filter 510R can have a shorter length than the green color filter 510G in the first direction X. Thus, in the display apparatus according to another embodiment of the present disclosure, the quality of the image three-dimensionally recognized by the user can be improved by the second pixel area PA2 of each pixel row Pc.

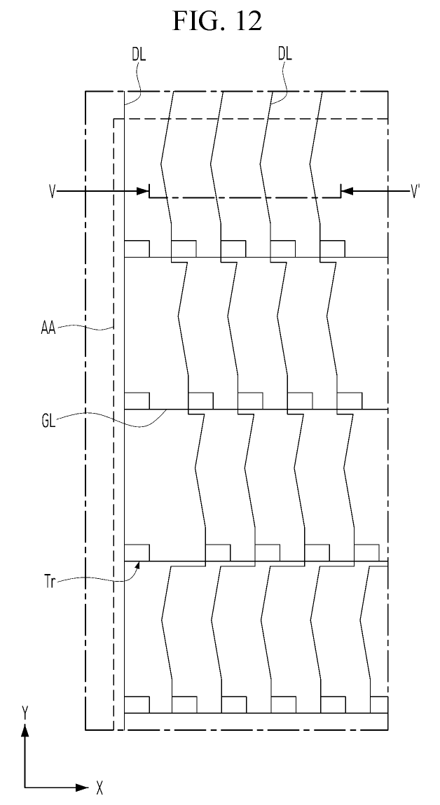

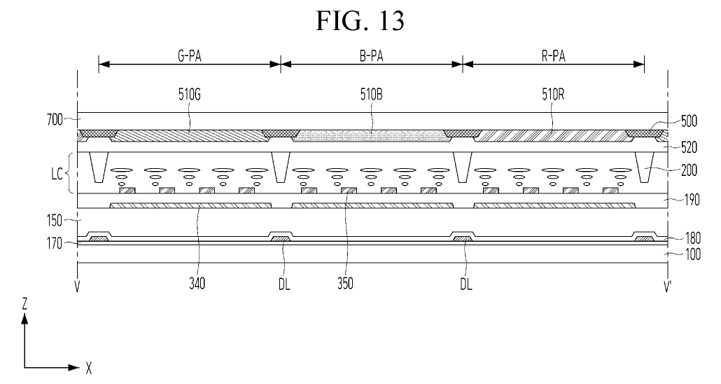

The display apparatus according to the embodiment of the present disclosure is described that each of the pixel areas PA includes the light-emitting device 300. However, in the display apparatus according to another embodiment of the present invention, a variety of the display panels DP can be used. For example, in the display apparatus according to another embodiment of the present disclosure, the display panel DP can be a liquid crystal panel in which a liquid crystal layer LC and an encapsulation substrate 700 are stacked on the device substrate 100, as shown in FIGS. 12 and 13. FIG. 13 is an example of a view taken along line V-V’ of FIG. 12.

A lower insulating layer 170, an upper insulating layer 180, an electrode passivation layer 190, a common electrode 340 and a pixel electrode 350 can be disposed between the device substrate 100 and the liquid crystal layer LC. The gate line GL can be covered by the lower insulating layer 170. The data line DL can be disposed between the lower insulating layer 170 and the upper insulating layer 180. A thickness difference due to the gate line GL and/or the data line DL can be removed by the device planarization layer 150 disposed between the upper insulating layer 180 and the electrode passivation layer 190. The common electrode 340 can be disposed between the device planarization layer 150 and the electrode passivation layer 190. The pixel electrode 350 can be disposed between the electrode passivation layer 190 and the liquid crystal layer LC.

An upper passivation layer 520 covering the barrier pattern 500 and the color filters 510R, 510G and 510B can be disposed between the liquid crystal layer LC and the encapsulation substrate 700. The barrier pattern 500 can function as a black matrix. The barrier pattern 500 and the color filters 510R, 510G and 510B can be disposed between the upper passivation layer 520 and the encapsulation substrate 700. Spacers 200 for maintaining a gap between the electrode passivation layer 190 and the upper passivation layer 520. For example, the common electrode 340 and the pixel electrode 350 can be disposed between the spacers 200.

The data line DL disposed adjacent to an edge of the display area AA can have a different shape from another data line DL. For example, the data line DL disposed adjacent to an edge of the display area AA can extend parallel to a side surface of the display area AA. The data line DL disposed adjacent to the edge of the display area AA can extend in the second direction Y. The data lines DL in other areas can extend in a non-parallel or non-straight manner. Thus, in the display apparatus according to another embodiment of the present disclosure, a thin film transistor Tr in the second pixel area of each pixel row can be disposed adjacent to an edge of the display area AA. For example, in the display apparatus according to another embodiment of the present disclosure, a length of the second pixel area of each pixel row Pc in the first direction X can be increased by using the data line DL. Therefore, in the display apparatus according to another embodiment of the present disclosure, the degree of freedom in the configuration of display panel can be improved.

As a result, the display apparatus according to the embodiments of the present disclosure can comprise the display panel including the pixel areas and the lenticular lenses on the display panel, wherein the lenticular lenses disposed side by side in the first direction can extend in the second direction perpendicular to the first direction, wherein each of the pixel rows of the display panel disposed side by side in the second direction can include the pixel areas repeated in a specific order in the first direction, wherein each of the pixel rows can include the first pixel areas having a same size and the second pixel area having a longer length than each first pixel area in the first direction, and wherein the second pixel area of each pixel row can be disposed between an edge of the display panel and the first pixel areas of the corresponding pixel row. Thus, in the display apparatus according to the embodiments of the present disclosure, the occurrence of spots in the image three-dimensionally recognized by the user can be prevented or minimized. Thereby, in the display apparatus according to the embodiments of the present disclosure, the image can be improved. Further, in the display apparatus according to the embodiments of the present disclosure, the production energy can be reduced by the process optimization.

What is claimed is:

1. A display apparatus comprising:
a display panel including pixel rows, each of the pixel rows including pixel areas configured to display different colors, the pixel areas of each pixel row being repeated in a specific order in a first direction; and
lenticular lenses on the display panel, the lenticular lenses extending in a second direction different from the first direction,
wherein each of the pixel rows disposed side by side in the second direction includes first pixel areas having a same size and a second pixel area having a longer length than each first pixel area in the first direction, and
wherein the second pixel area of each pixel row is disposed between an edge of the display panel and the first pixel areas of the corresponding pixel row.

2. The display apparatus according to claim 1, wherein a distance between the edge of the display panel and each pixel row is the same.

3. The display apparatus according to claim 1, wherein the pixel rows include a first pixel row and a second pixel row disposed adjacent to the first pixel row in the second direction,
wherein each first pixel area of the second pixel row has a same size as each first pixel area of the first pixel row, and
wherein the second pixel area of the second pixel row has a different length from the second pixel area of the first pixel row in the first direction.

4. The display apparatus according to claim 3, wherein the second pixel area of the second pixel row has a same length as the second pixel area of the first pixel row in the second direction.

5. The display apparatus according to claim 3, wherein the pixel rows further include a third pixel row disposed adjacent to the second pixel row in the second direction, and
wherein each first pixel area of the third pixel row has a same size as each first pixel area of the second pixel row.

6. The display apparatus according to claim 5, wherein the second pixel area of the third pixel row has a same size as the second pixel area of the first pixel row in the first direction.

7. The display apparatus according to claim 6, wherein the second pixel area of the second pixel row is configured to display a different color from the second pixel area of the first pixel row, and
wherein the second pixel area of the third pixel row is configured to display a different color from the second pixel area of the first pixel row and the second pixel area of the second pixel row.

8. The display apparatus according to claim 6, wherein a difference in the length of the second pixel area of the second pixel row and the second pixel area of the third pixel row in the first direction is a same as a difference in the length of the second pixel area of the first pixel row and the second pixel area of the second pixel row in the first direction.

9. The display apparatus according to claim 8, wherein a difference in the length of the second pixel area of the first pixel row and the second pixel area of the second pixel row in the first direction is smaller than a length of each first pixel area of the first pixel row in the first direction.

10. The display apparatus according to claim 6, wherein the display panel includes a display area, and the display area includes a first side extending in the second direction and a second side opposite to the first side,
wherein the second pixel area of the first pixel row is disposed adjacent to the first side of the display area, and
wherein the second pixel area of the third pixel row is disposed adjacent to the second side of the display area.

11. The display apparatus according to claim 10, wherein the second pixel area of the second pixel row disposed between the first pixel row and the third pixel row is disposed between the first side of the display area and the first pixel areas of the second pixel row, and between the first pixel areas of the second pixel row and the second side of the display area.

12. The display apparatus according to claim 10, wherein, a data signal is applied in the pixel area through data lines, and
wherein the data lines include a first data line disposed adjacent to an edge of the display area extending in the second direction in parallel to a side surface of the display area and a second data line having a different shape from the first data line.

13. The display apparatus according to claim 1, further comprising color filters in the pixel areas of each pixel row, and the color filters include a first color filter and a second color filter, and
wherein the second pixel area of each pixel row includes the first color filter and the second color filter disposed side by side with the first color filter in the first direction.

14. The display apparatus according to claim 13, wherein the second color filter includes a different material from the first color filter.

15. The display apparatus according to claim 13, wherein the first color filter is disposed between an edge of the display panel and the second color filter,
wherein a length of the second color filter in the first direction is same as a length of each first pixel area in the first direction, and
wherein a length of the first color filter in the first direction is smaller than the length of the second color filter in the first direction.

16. The display apparatus according to claim 13, wherein one of the lenticular lenses covers four different color filters, and the four different color filters include a red color filter, a green color filter, a blue color filter, and one of red, green and blue color filters.

17. The display apparatus according to claim 1, wherein display panel can include a display area including the pixel rows and a bezel area adjacent to the display area, and
wherein the lenticular lenses cover the display area and the bezel area.

18. The display apparatus according to claim 1, wherein the display panel further includes data lines configured to supply data signals, and
wherein at least one of the data lines extending in an edge portion of the display area has a different shape from at least another of the data lines extending in another portion of the display area.

19. The display apparatus according to claim 18, wherein the at least one of the data lines extends in a straight line, while the at least another of the data lines extends in a non-straight line.
